(19) United States
(12) Patent Application Publication
(10) Pub. No.: US 2025/0254847 A1
(43) Pub. Date: Aug. 7, 2025

(54) HOUSING AND CHARGING DEVICE FOR AN ELECTRICALLY POWERED VEHICLE

(71) Applicant: AUDI AG, Ingolstadt (DE)

(72) Inventor: Markus THURMEIER, Adlkofen (DE)

(21) Appl. No.: 19/041,778

(22) Filed: Jan. 30, 2025

(30) Foreign Application Priority Data
Feb. 1, 2024 (DE) 102024102859.9

(51) Int. Cl. H05K 7/20; B60L 53/302; F28D 20/00

(52) U.S. Cl. CPC H05K 7/20927; B60L 53/302; F28D 20/0034

(57) ABSTRACT

A housing for a heat source is disclosed, and may include an outer shell enclosing an interior space, a heat source arranged in the interior space, a heat storage unit, a heat transport connection, a coolant, at least one heat release unit, and a heat dissipation connection. The heat source may be connected to the heat storage unit via the heat transport connection, and the coolant may transport heat released by the heat source from the heat source to the heat storage unit via the heat transport connection. The heat dissipation connection may thermally connect the heat storage unit to the heat release unit, and the heat dissipation connection may transfer heat intermittently stored in the heat storage unit to the heat release unit with a time delay. A charger with such a housing, and a method for dissipating heat from a heat source are also disclosed.

### BACKGROUND

### Technical Field

The disclosure relates to a housing for a heat source, such as a charger. The disclosure further relates to a method for dissipating heat from a heat source.

### Description of the Related Art

Charging systems or charging devices for electrically powered vehicles often generate large amounts of waste heat, which must be dissipated from the charging devices to ensure stable operation of these devices. Such charging devices therefore usually have an active cooling system that dissipates the resulting waste heat from the housing of the charging device using electrical energy. In some cases, a large amount of electrical energy is required to operate such an active cooling system, particularly if the charging device is of a compact design. In addition, active cooling systems usually generate loud noises, for example from fans, which are perceived as disturbing in the vicinity of a charging device. For this reason, legal regulations can be expected in the future that define noise limits for charging devices in public spaces and prohibit the operation of charging devices that exceed these noise limits.

DE102016101115A1 describes a conductive vehicle charging port with a cooling infrastructure. The cooling infrastructure uses a coolant to dissipate heat from the charging port and release the heat into the surroundings. The cooling infrastructure may also have a heat sink that dissipates a heat flow from the charging port directly into the surroundings.

U.S. Pat. No. 11,745,612 B1 describes a method and a system for temperature management of an electric charging system for a vehicle. The system may comprise a cooling plate which absorbs heat from a charging equipment and uses the absorbed heat to evaporate a coolant inside the cooling plate. The vaporous coolant is in turn fed to a condenser, where the coolant is condensed back into a liquid state while releasing heat to the surroundings.

CN213472824U describes a high-performance charging unit with stable heat dissipation. The charging unit comprises several cooling fans and thermally conductive plates arranged on the outside of the charging unit. Waste heat generated inside the charging unit is dissipated by convection and heat conduction in combination from the housing surrounding the charging unit.

### BRIEF SUMMARY

The present disclosure enables an electrically powered vehicle to be charged reliably, with reduced noise generation and reduced energy requirements for cooling the charging device used.

The present disclosure provides a housing for receiving a heat source, which may comprise:
an outer shell which encloses an interior space,
a heat source which intermittently releases heat and which is arranged in the interior,
a heat storage unit which is arranged in the interior and which is provided to intermittently store heat released by the heat source,
at least one heat release unit which is arranged in the outer shell or forms a portion of the outer shell,
wherein the heat source may be fluidly connected to the heat storage unit via a heat transport connection and a coolant may transport heat released by the heat source from the heat source to the heat storage unit via the heat transport connection,
wherein the heat storage unit may comprise at least one heat storage plate, against or around which the coolant flows and is configured to absorb heat from the coolant, and a heat dissipation connection may be provided which thermally connects the heat storage unit to the heat release unit, wherein the heat dissipation connection is configured to transfer heat intermittently stored in the heat storage unit to the heat release unit at least partially with a time delay for releasing the heat by the heat source, and the heat release unit is configured to dissipate this transferred heat from the housing, wherein a first heat flow that can be transferred from the heat source to the heat storage unit via the heat transport connection is greater than a second heat flow that can be dissipated from the housing by the heat release unit, in particular wherein the first heat flow is at least twice as large as the second heat flow.

The housing according to the present disclosure may be configured to receive a heat source and may further comprise components which are configured to initially intermittently store heat in the housing and subsequently or simultaneously to dissipate this intermittently stored heat to outside the housing. The housing according to the present disclosure may be used, for example, as a housing of a charging device for charging an electrically powered vehicle. In addition, the housing according to the present disclosure may also be used to receive and protect other heat sources, for example a data processing module, a radio module or the like. The housing is described below in connection with a charging device for an electrically powered vehicle, wherein the heat source is formed by a power module of such a charger. However, the present disclosure is expressly not limited to such an application of the housing.

The housing according to the present disclosure may comprise an outer shell which encloses an interior. Here, the outer shell may be substantially closed, but may have openings for the passage of cables and for enabling gas exchange between the interior and the surroundings of the housing. The outer shell may be configured to protect the components arranged in the interior, including the heat source, and to separate such components from the surroundings. At least one heat source may be arranged in the interior of the housing, which at least intermittently releases heat, which then accumulates in the interior. The heat source preferably releases heat discontinuously, i.e., intermittently. At some times, the heat source may release a large amount of heat, at other times a smaller amount of heat, or no heat at all. The heat source may be formed, for example, by power electronics for charging an electric vehicle. At least one heat storage unit may be arranged inside the housing, which is provided to store heat released by the heat source. For this purpose, the heat storage unit may have a high heat storage capacity, i.e., the heat storage unit is configured to absorb and intermittently store large amounts of heat. The housing may further comprise a heat release unit which is arranged in or on the outer shell. This heat release unit is configured to release heat from the interior of the housing, and in particular from the heat storage unit, to outside the housing. It is also possible for the heat release unit to form part of the outer shell.

The heat source may be connected to the heat storage unit via a heat transport connection, which fluidly transports a coolant from the heat source to the heat storage unit. The heat transport connection may be formed, for example, by a pipe that guides and transports coolant from the heat source to the heat storage unit. The heat storage unit may comprise at least one heat storage plate with flow against or around it by coolant which flows loaded with heat from the heat source into the heat storage unit. The heat storage plate is the energy storage in the heat storage unit and initially absorbs heat from the coolant and stores it there. The heat storage plate preferably has a large surface area in order to enable rapid heat transfer from the coolant to the heat storage plate. Preferably, several heat storage plates may be provided, which are arranged in the manner of a labyrinth in the heat storage unit, so that coolant flowing past comes into contact with several heat storage plates and may thus transfer a large amount of heat energy to the heat storage unit in a short time. Preferably, the at least one heat storage plate may be arranged in a housing of the heat storage unit. This housing of the heat storage unit preferably has a coolant inlet through which warm coolant is introduced from the heat source into the heat storage unit. In addition, the heat storage unit may preferably have a coolant outlet which leads cooled coolant, which has given off at least a large part of its thermal energy to the heat storage plate, out of the housing of the heat storage unit. The housing according to the present disclosure may further comprise a heat dissipation connection which transports heat intermittently stored in the heat storage unit to the heat release unit. This heat dissipation connection may be configured in different ways and may be formed, for example, by a pipe connection which connects the heat storage unit to the heat release unit. The heat release unit finally dissipates the heat intermittently stored in the heat storage unit to outside the housing. The heat release unit may also be configured in different ways and may be formed, for example, by an opening in the housing through which coolant flows from the housing to the outside. Alternatively or additionally, the heat release unit may also be formed by a closed portion of the outer shell.

According to the present disclosure, a first heat flow that may be transferred from the heat source to the heat storage unit may be greater than a second heat flow that may be dissipated from the heat storage unit out of the housing via the heat release unit. Here, heat flow is understood to mean an amount of heat transferred per unit of time. If a relatively large amount of heat is intermittently generated by the heat source, this amount of heat may initially be transferred in the form of a first heat flow from the coolant to the heat storage unit and stored there. The coolant and the heat transport connection may be configured in such a way that a large first heat flow may be transferred from the heat source to the heat storage unit. A large amount of heat may be generated by the heat source, for example, when an electric vehicle with a low charge level is plugged into a charger. After plugging in, a relatively high charging current may be transferred to the vehicle, which may generate a large amount of waste heat in the corresponding power electronics. During the charging process of the electric vehicle, the charging current may drop, which may also reduce the amount of waste heat released. Once the charging process of an electric vehicle is complete, the power electronics may no longer generate a significant amount of heat. According to the present disclosure, the time-dependent amount of heat generated by the heat source may first be transferred to the heat storage unit via a powerful thermal connection and intermittently stored there. Heat may subsequently or simultaneously be transported from the heat storage unit to outside the housing in the form of a second heat flow. In this case, according to the present disclosure, the second heat flow may be smaller than the first heat flow; typically, the second heat flow may be significantly smaller than the first heat flow. Because the second heat flow may be significantly smaller than the first heat flow, which is required to dissipate peak power from the heat source, significantly less power may be required to dissipate the heat from the housing compared to known housings. The concept according to the present disclosure is to dissipate heat from the housing with a lower heat flow than is generated in the housing by the heat source at peak times. This is made possible by the fact that the heat storage unit is provided inside the housing, which can intermittently store large amounts of heat without having to dissipate it directly to outside the housing. The heat dissipation connection and the heat release unit, which act as cooling for the housing, may thus be made significantly smaller in size, which means that they require less energy to operate. In addition, a housing according to the present disclosure may produce significantly less noise when dissipating the waste heat than with known solutions. For example, it is possible to configure the housing to be completely closed and to dissipate the second heat flow through a portion of the outer shell of the housing. The housing according to the present disclosure thus makes it possible to charge an electrically powered vehicle with reduced energy requirements for cooling and a reduced noise level. A charger or power electronics for charging an electric vehicle may be operated reliably, since high levels of waste heat that are generated intermittently may be transferred safely and over a short distance to the heat storage unit, thereby preventing the power electronics from overheating.

In some embodiments, the heat storage unit may comprise several heat storage plates, which may be arranged partially spaced apart from one another in the manner of a labyrinth, wherein the coolant may flow against or around the heat storage plates one after the other, wherein the heat storage plates may guide the coolant from an interface between the heat transport connection and the heat storage unit through the heat storage unit to an interface between the heat storage unit and the heat dissipation connection. In such embodiments, several heat storage plates may be provided, which may be arranged in the heat storage unit in such a way that the coolant flows against or around them one after the other or simultaneously. This configuration enables efficient heat transfer from the coolant to a large surface of the heat storage plates. The coolant may be guided between the heat storage plates on as long a path as possible in the manner of a labyrinth. The heat storage plates may form a type of guide path for the coolant. The heat storage unit may preferably comprise a housing which has an interface between the heat transport connection and the heat storage unit, which may also be referred to as a coolant inlet. The heat storage unit furthermore may comprise an interface between the heat storage unit and the heat dissipation connection, which may also be referred to as a coolant outlet. The heat storage plates may be arranged between the coolant inlet and coolant outlet in such a way that the coolant preferably flows against the heat storage plates on both sides in order to be able to use the available surface for heat transfer as optimally as possible. As an alternative to several heat storage plates that are partially spaced apart from one another, a single, large and complexly shaped heat storage plate may also be provided, which may, for example, have the shape of a spiral.

In some further embodiments, the at least one heat storage plate may be constructed in multiple layers and may comprise a material with high thermal conductivity in an outer layer and a material with high heat storage capacity in an inner layer, wherein the outer layer transfers heat from the coolant to the inner layer and the inner layer intermittently stores the heat. A material with high thermal conductivity may be selected, for example, from a group comprising aluminum or aluminum sheet, copper or copper sheet, steel, and plastic. A low-melting plastic, for example having a melting point in the range of 30° C.-90° C., or a combination of several such plastics, in particular selected from the group of n-alkanes, may be selected as a material with high heat storage capacity. A material from the group of PCMs (phase change materials) may also be selected, for example, as a material with high heat storage capacity. This may be a material that changes its phase at a transition temperature in the range of 30° C.-90° C. (+/−10° C.).

In such embodiments, the heat storage plate may be constructed in multiple layers, with the different layers taking on different functions. An inner layer arranged on the inside may be configured for storing or intermittently storing heat. Such an inner layer may have a material with high thermal conductivity in order to be able to intermittently store as much heat as possible. An outer layer surrounding the inner layer may preferably comprise a material that has a very high thermal conductivity. The outer layer may absorb the heat from the coolant flowing past and may conduct the heat into the interior of the heat storage plate to the inner layer, where it is stored. In the case where the coolant flows in at a temperature that is lower than that of the heat storage plate, the heat stored in the heat storage plate may be transferred back to the coolant and dissipated by the coolant. The heat stored in the inner layer may then be transferred through the outer layers to the coolant and dissipated by the coolant.

In some further embodiments, the at least one heat storage plate may comprise a phase change material in some areas, which undergoes a phase change from the solid to the liquid phase and vice versa when intermittently storing heat and may absorb or release latent heat in the process, in particular wherein the phase change material is arranged in an inner layer according to the previously described embodiment. A phase change material may be a material or a component which has a phase transition or phase change between the solid and the liquid phase in the temperature range in which the heat storage plate is used, in particular in a temperature range between −20° C. and 150° C. If, for example, a phase change material is used in a heat storage plate which changes from the solid to the liquid state at 70° C., this phase change material absorbs latent heat at 70° C. in addition to normal heat storage. Latent heat is required to enable the phase transition. Due to the additional absorption of latent heat, the total achievable heat absorption capacity is greater with a phase change material than with a material which does not undergo a phase change in the temperature range of the heat storage unit. A phase change material may therefore achieve a higher heat absorption capacity in the same installation space. When cooling down or releasing heat back to the coolant, in a case in which the heat source releases little or no heat, a phase change occurs in the opposite direction from the liquid phase to the solid phase. In this case, the previously absorbed latent heat is released back into the coolant. Such a phase change material may be, for example, a low-melting plastic, e.g., having a melting point in the range of 30° C.-90° C., or a combination of several such plastics, in particular selected from the group of n-alkanes.

In some embodiments, the coolant may be formed by air, the coolant moving passively by free convection from the heat source through the heat transport connection to the heat storage unit, or a coolant pump may be provided in or on the housing, which may actively transport the coolant from the heat source through the heat transport connection to the heat storage unit. Air is a suitable coolant because it is always present and can also be drawn in from outside the housing. Of course, it is also possible to transport the heat in the housing using another coolant, for example water or oil. The coolant may be transported passively in the housing. Such a configuration may be accomplished due to the effect of coolant loaded with heat or heated reduces its density and thus rises vertically upwards by itself. If air is used as a coolant, for example, the heated air may rise from the heat source towards the heat storage unit. Conversely, if heat has been intermittently stored in the heat storage unit, heated coolant from the heat storage unit may also rise upwards through this free convection. This may create a suction effect in the heat storage unit, which draws in cool air from below and in this way removes the second heat flow from the heat storage unit and the housing without the need for active components. A housing in which heat is transported inside and to the outside by free convection may have a particularly low energy requirement for cooling the heat source, since no active components, such as a coolant pump, are required to be operated. In order to increase the performance of heat transport in the housing, a coolant pump may be used as an alternative or in addition to free convection, which transports the coolant within the housing. However, due to the possibility of intermittently storing heat in the heat storage unit in the housing according to the present disclosure, this coolant pump may be made smaller in size than in known housings. It is also possible for a coolant pump to be activated only intermittently, in particular when the heat released by the heat source is at peak levels, and for heat to otherwise be transported only by free convection. To control and regulate the coolant pump, a temperature sensor may be provided in combination with a control unit, which may only activate the coolant pump when required.

In some further embodiments, the heat release unit may be configured as an opening in the outer shell of the housing and the heat dissipation connection may be configured as a pipe which fluidly connects the heat storage unit to the heat release unit, wherein coolant flowing through the heat release unit to outside the housing dissipates the second heat flow from the housing. In such embodiments, the outer shell of the housing may have at least one opening which forms a heat release unit. The second heat flow from the heat storage unit to outside the housing may be dissipated by convection. The coolant may absorb heat in the heat storage unit and may transport the heat to outside the housing. It is advantageous that, due to the heat storage capacity of the heat storage unit, a small second heat flow may be sufficient to continuously dissipate heat from the housing. This means that the amount of coolant per unit time which is dissipated from the housing may be reduced compared to known solutions. This may also reduce the noise pollution for the surroundings which is generated by the coolant flowing out of the heat release unit.

In some embodiments, the heat release unit may form a portion of the outer shell and the heat dissipation connection may be formed at least partially by coolant located in the interior, which transports heat from the heat storage unit to the heat release unit by convection and/or heat conduction, wherein the heat release unit may comprise at least one heat transfer plate, which dissipates the second heat flow from the housing by heat conduction. In such embodiments, it is possible to configure the outer shell to be completely closed. The dissipation of the second heat flow takes place by heat conduction, which may be carried out by at least one heat transfer plate, which forms part of the outer shell. For example, a large-area heat transfer plate made of copper or aluminum, which has a very high thermal conductivity, may be provided as part of the outer shell. The heat may be transported within the housing by convection or heat conduction by the coolant or other components installed in the housing from the heat storage unit to the heat release unit, which may be configured as a heat transfer plate. The heat transfer plate may in turn dissipate the heat by heat conduction to its outside, where the heat may be released into the surroundings of the housing. Such an embodiment may not generate any noise when the heat is dissipated to outside the housing and may therefore be very quiet. It is also possible to configure the heat transfer plate as further intermediate storage for heat, for example using a phase change material, as previously described in an embodiment of the heat storage plate of the heat storage unit. Such a heat transfer plate, which, at the same time, has the function of a heat storage plate, at the same time, serves as thermal insulation for the housing and may protect the interior of the housing from extreme temperatures that prevail outside the housing. Furthermore, it is possible to combine a heat release unit configured as a heat transfer plate with a heat release unit configured as an opening in the outer shell.

The present disclosure may further provide a charging device for an electrically powered vehicle, which may comprise:
a housing according to any one of the previously described embodiments,
at least one plug-in connector which is connected to the housing via electrical lines and is configured for connection to an electrically powered vehicle,
wherein the heat source may be formed by power electronics for providing a charging current for an electrically powered vehicle and the first heat flow conducts heat, which is released by the power electronics when charging an electrically powered vehicle, to the heat storage unit and the second heat flow dissipates the heat intermittently stored in the heat storage unit to outside the housing at least partially with a time delay for charging the electrically powered vehicle.

The charging device according to the present disclosure may be arranged in a housing according to any one of the previously described embodiments. The charging device may be arranged both in an electrically powered vehicle and outside of such a vehicle. It is also possible for the charging device to be stationary, as a charging station. In the charging device according to the present disclosure, the heat source in the housing may be formed by power electronics, which may provide the charging current for charging an electrically powered vehicle. Such power electronics may intermittently generate a high level of waste heat, which may initially be intermittently stored in the housing according to the present disclosure by the intermediate storage unit. The first heat flow of the charging device may thus be directed from the power electronics to the heat storage unit. The second, smaller heat flow may be directed from the heat storage unit to outside the housing, as previously described in connection with the housing. When charging an electric vehicle, a high level of waste heat may be intermittently generated in or on the power electronics, particularly when a high charging current must be provided. However, such a high charging current may only need to be made available intermittently; at other times, for example when the electrically powered vehicle is already largely charged, only a small charging current may be required, which may also generate a smaller amount of waste heat. The charging device according to the present disclosure may initially store large amounts of waste heat that are generated for a short time in the heat storage unit without having to dissipate the heat to outside the housing. Subsequently or at the same time, the intermittently stored heat may continuously be dissipated from the heat storage unit to outside the housing in a smaller heat flow. This dissipation of heat to outside the housing may continue even when the power electronics as a heat source no longer generates waste heat. Since a charging device according to the present disclosure may only require a small second heat flow directed to outside the housing due to the possibility of intermittently storing heat, significantly less energy may be needed to cool the charging device than with known solutions. In addition, the noise pollution or the noise level generated during charging may be significantly lower. However, due to the possibility of directing a high initial heat flow from the heat source to the heat storage unit, it is ensured at the same time that the heat may be reliably dissipated from the power electronics and said power electronics thus does not overheat.

The present disclosure also provides a method for dissipating heat from a heat source, wherein a housing of one of the previously described embodiments is used to carry out the method, in which the heat source is arranged, and the method may comprise:
transferring a first heat flow from the heat source to the heat storage unit via the heat transport connection,
intermittently storing the heat from the first heat flow in the heat storage unit,
dissipating a second heat flow to outside the housing, wherein the second heat flow dissipates the heat intermittently stored in the heat storage unit to the heat release unit via the heat dissipation connection, and from there to outside the housing,
wherein the dissipating of the second heat flow may be carried out at least partially with a time delay to the first heat flow and the first heat flow may be greater than the second heat flow.

The method according to the present disclosure serves to dissipate heat from a heat source, in particular in a charging device for charging an electrically powered vehicle. The method according to the present disclosure is based on the concept of initially intermittently storing large amounts of heat arising dynamically, i.e., only intermittently, and released by the heat source in a heat storage unit and then continuously releasing heat from the heat storage unit to the surroundings.

In a first method step, heat may be transferred from the heat source in a first heat flow to or into a heat storage unit. This first heat flow may be guided via a heat transport connection.

In a second method step, the amount of heat transferred by the first heat flow may be stored in the heat storage unit. For this purpose, the heat storage unit may comprise at least one heat storage plate which absorbs the transferred heat.

In a third method step, the heat intermittently stored in the heat storage unit may be continuously dissipated to outside the housing in a second heat flow. The second heat flow may be guided to outside the housing via a heat dissipation connection and a heat release unit. According to the present disclosure, the third method step may be carried out at least partially at different times than the first method step. In particular, the third method step may be continued after completion of the first method step. In this way, an intermittently high first heat flow in the housing may be compensated for by a smaller second heat flow that is continuously dissipated over a longer period of time. The method according to the present disclosure thus may enable energy-efficient cooling of the heat source and may generate little noise pollution in the surroundings of the housing.

Alternatively, it is also possible that instead of the third method step, a fourth method step may be carried out, which provides for a temporary shutdown of the heat release unit, the heat dissipation connection, and/or the coolant pump so that the intermittently stored heat of the heat storage plates remains in the housing in order to temper the housing at low temperatures.

In some embodiments of the method, the heat source may be formed by power electronics of a charging device for an electrically powered vehicle and the transfer of the first heat flow in the first method step may be used to cool this power electronics. In such embodiments, the heat source may be formed by power electronics for charging an electrically powered vehicle. In such embodiments, the method may serve to dissipate waste heat from the power electronics and to ensure stable operation of the power electronics. The method may thus be used to cool power electronics when charging an electrically powered vehicle.

Features, effects and advantages which are disclosed in connection with the housing are also deemed to be disclosed in connection with the charging device and the method. The same applies in the reverse direction; features, effects and advantages which are disclosed in connection with the method and the charging device are also deemed to be disclosed in connection with the housing.

### BRIEF DESCRIPTION OF THE SEVERAL VIEWS OF THE DRAWINGS

FIG. 1 shows a schematic, sectional view of an embodiment of a charging device according to the present disclosure.

FIG. 2 shows a schematic, sectional view of a second embodiment of a heat storage unit of a housing according to the present disclosure.

FIG. 3 shows a schematic, sectional view of a third embodiment of a heat storage unit of a housing according to the present disclosure.

FIG. 4 shows a schematic, sectional view of a fourth embodiment of a heat storage unit of a housing according to the disclosure.

### DETAILED DESCRIPTION

FIG. 1 shows a schematic, sectional view of an embodiment of a charging device according to the present disclosure. The charging device shown is provided for charging an electrically powered vehicle. The charging device may comprise a housing 1, which may protect the parts and components arranged in an interior 12 of the charging device. A heat source 13 in interior 12 may be formed by power electronics for providing a charging current for the electrically powered vehicle. The charging device may comprise a schematically shown plug-in connection 19, which may be connected to heat source 13 via electrical lines (not shown). To charge the electrically powered vehicle, the plug-in connection 19 may be connected to the vehicle. The charging device may be configured to be stationary or fixed as a charging dock or charging station. Alternatively, the charging device may also be formed by a mobile device that is arranged in or on the vehicle or may at least be transported in the vehicle. Housing 1 may be surrounded by an outer shell 11, which here has a cuboid shape. Outer shell 11 encloses interior 12, which, in the embodiment shown, is filled with air. Heat source 13, which may be formed by power electronics, is arranged on the right in interior 12 in the embodiment shown. Heat source 13 releases heat, with the amount of heat released varying over time. A heat storage unit 14, which is configured for the temporary storage of heat, is arranged at the top left next to heat source 13 in the embodiment shown. Heat source 13 may be fluidly connected to heat storage unit 14 by a heat transport connection 15. In the embodiment shown, air is used as a coolant to dissipate heat from heat source 13. The coolant formed by air may flow from heat source 13, where the coolant absorbs heat, through heat transport connection 15 into heat storage unit 14. In the embodiment shown, heat transport connection 15 may be formed by a pipe which connects heat source 13 to heat storage unit 14. In the embodiment shown, heat is dissipated from housing 1 via two heat release units 16 acting in parallel. A first heat release unit 16 is arranged to the left of heat storage unit 14 and is formed by an opening in outer shell 11 in the embodiment shown. A heat dissipation connection 17, which may be configured as a pipe, fluidly connects heat storage unit 14 to heat release unit 16. In this way, coolant formed by air may be led from heat storage unit 14 through heat dissipation connection 17 and heat release unit 16 out of housing 1. In doing so, a second heat flow may be transported to the outside by the coolant led out of housing 1. Acting parallel to heat release unit 16, which may be configured as an opening, a second heat release unit 16 may be arranged at the top of housing 1 and may be configured as a portion of outer shell 11. The heat release unit 16 integrated into outer shell 11 may be formed by a heat transfer plate which may have a high thermal conductivity and may dissipate a second heat flow from housing 1 by heat conduction. The transport of the heat intermittently stored in heat storage unit 14 to heat release unit 16, which may be configured as a heat transfer plate, may take place via the coolant present in interior 12, which may transport heat from heat storage unit 14 to heat release unit 16 by convection and/or heat conduction. In the embodiment shown, a coolant pump 18 may also arranged in housing 1, which may actively move or transport the coolant, which here is formed by air, in interior 12 of housing 1. Coolant pump 18 may be configured as a fan, for example. Coolant pump 18 may first move coolant to heat source 13, where the coolant absorbs heat. The heated coolant may then be moved through heat transport connection 15 into heat storage unit 14, where the coolant releases heat. At least part of the coolant may then be led from heat storage unit 14 through heat release unit 16, which may be configured as an opening, to outside the housing. In this case, part of the coolant may also be led from heat storage unit 14 back into interior 12 of housing 1, for example in order to transport heat to heat release unit 16, which may be configured as a heat transfer plate. Coolant pump 18 is optional, however, and may also be omitted. Without coolant pump 18, the coolant may move through free convection from heat source 13 through heat transport connection 15 into heat storage unit 14. For this purpose, heat transport connection 15 may be connected to heat source 13 on the upper side of heat source 13. In this way, coolant heated by heat source 13 may rise due to its lower density and may move towards heat storage unit 14.

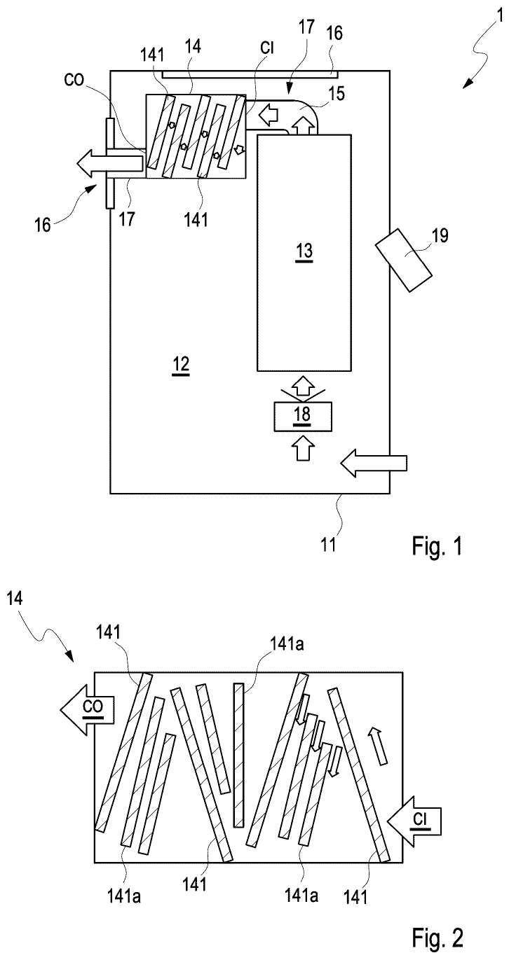

Heat storage unit 14 in the embodiment shown in FIG. 1 comprises several heat storage plates 141, which are arranged spaced apart from and parallel to one another in a housing of heat storage unit 14. Heat storage plates 141 may be arranged in the manner of a labyrinth. In this way, the coolant flowing into heat storage unit 141 may be guided on a long path between and through heat storage plates 141. The heated coolant may thus reach a very large surface of heat storage plates 141 and may thus quickly and efficiently transfer heat to heat storage plates 141 or absorb heat from heat storage plates 141. Alternative embodiments for the arrangement of one or more heat storage plates 141 in heat storage unit 14 are shown in FIGS. 2 to 4 and described. Heat storage plates 141 may guide the coolant in heat storage unit 14 from an interface between heat transport connection 15 and heat storage unit 14, which may also be referred to as the coolant inlet CI, through heat storage unit 14 to an interface between heat storage unit 14 and heat dissipation connection 17, which may also be referred to as the coolant outlet CO. Heat storage plates 141 may thus define a coolant guide path which guides the coolant through heat storage unit 14. Heat storage plates 141 may be configured in such a way that the heat storage plates 141 may have a high heat absorption capacity and may thus intermittently store a large amount of heat. For this purpose, heat storage plates 141 may be constructed in one layer or in multiple layers. Optionally, it is also possible for heat storage plates 141 to have a phase change material at least in some areas, which transitions from a solid to the liquid phase when heat is absorbed. This phase transition may enable the heat storage plates 141 to store a larger amount of heat than in materials which do not undergo a phase transition when heat is absorbed.

For waste heat utilization of the heat intermittently stored in heat storage plates 141, heat release unit 16, heat dissipation connection 17 and/or coolant pump 18 may be switched off so that the stored heat of heat storage plates 141 may remain in housing 1 and in interior 12 in order to temper housing 1 and interior 12 at low temperatures.

FIG. 2 shows a schematic, sectional view of a second embodiment of a heat storage unit 14 of a housing 1 according to an embodiment of the present disclosure. In the previously described FIG. 1, a heat storage unit 14 according to a first embodiment is shown, which has several heat storage plates 141 arranged parallel to one another. In the second embodiment shown in FIG. 2, heat storage plates 141 are arranged at different angles to one another. Four large heat storage plates 141 may each be arranged at an acute angle to adjacent heat storage plate 141. These four large heat storage plates 141 may also form a labyrinth here, through which the coolant, symbolized by arrows, is guided. The coolant, in particular in the form of air, may be introduced here into the housing of heat storage unit 14 through coolant inlet CI, may pass through the labyrinth consisting of large heat storage plates 141 and may finally exit the housing of heat storage unit 14 through coolant outlet CO. Between four large heat storage plates 141, two smaller heat storage plates 141a may be arranged. The two smaller heat storage plates 141a may be arranged to be spaced apart from one another and at a distance from large heat storage plates 141. The coolant may also flow through small heat storage plates 141a at these distances. In this way, the coolant may flow around a very large surface of heat storage plates 141 and 141a on its way through heat storage unit 14 and may thus quickly transfer a large amount of heat into heat storage unit 14. The second embodiment of a heat storage unit 14 shown may preferably be installed in a housing 1 in such a way that the coolant flows from coolant inlet CI to coolant outlet CO substantially in a horizontal direction.

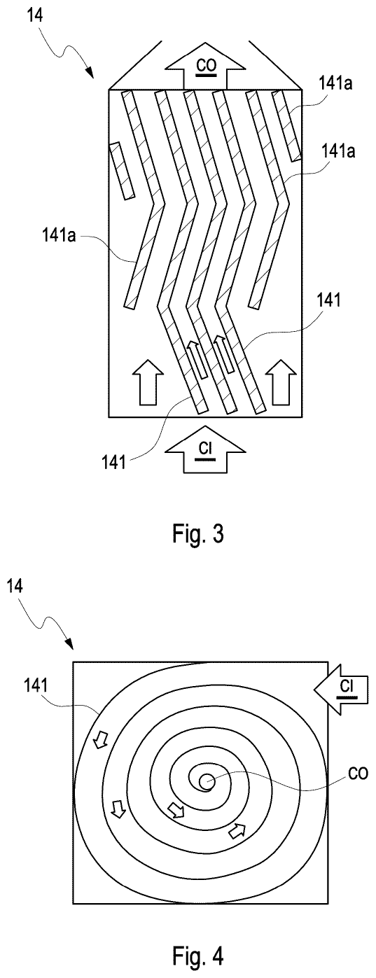

FIG. 3 shows a schematic, sectional view of a third embodiment of a heat storage unit 14 of a housing 1 according to an embodiment of the present disclosure. In this third embodiment too, a coolant, preferably air, flows through heat storage unit 14 from coolant inlet CI in the direction of coolant outlet CO. In contrast to the embodiment shown in FIG. 2, the embodiment shown in FIG. 3 is preferably installed in housing 1 in such a way that the coolant flows vertically upwards from coolant inlet CI arranged below to coolant outlet CO. This embodiment shown in FIG. 3 may particularly be suitable for housings 1 which do not have a coolant pump 18, but in which the transport of the coolant takes place solely by free convection. The coolant loaded with heat introduced at coolant inlet CI may rise through the housing of heat storage unit 14 and may leave the housing of heat storage unit 14 through coolant outlet CO. In the embodiment shown, several zigzag-shaped heat storage plates 141 may be arranged parallel to one another, with gaps between heat storage plates 141 through which the coolant may flow upwards. The zigzag shape may lengthen the flow path of the coolant, so that the coolant may remain in contact with a larger surface of heat storage plates 141 for longer. In this way, a faster and more efficient heat transfer between the coolant and heat storage plates 141 may be ensured. In this embodiment also, smaller heat storage plates 141a may be arranged on both sides in a horizontal direction outside large heat storage plates 141, which may also be arranged at a distance from one another through which coolant flows. This configuration may further increase the surface area of heat storage plates 141 and 141a with flow thereagainst. In addition, small heat storage plates 141a may also increase the total heat storage capacity of heat storage unit 14.

FIG. 4 shows a schematic, sectional view of a fourth embodiment of a heat storage unit 14 of a housing 1 according to an embodiment of the present disclosure. In the fourth embodiment shown in FIG. 4, heat storage unit 14 has only a single heat storage plate 141, which has the shape of a spiral. The coolant, loaded with heat, may be introduced through coolant inlet CI of the housing of heat storage unit 14. Heat storage plate 141 may extend into the plane of the drawing and the individual turns of heat storage plate 141 shaped as a spiral may be arranged at a distance from one another. The coolant may flow through this distance between the turns, whereby the coolant may cover a very large surface in all turns of heat storage plate 141. In this way, very good heat transfer between the coolant and heat storage plate 141 may be ensured. Inside the spiral, the coolant may then be led into the plane of the drawing through coolant outlet CO and out of the housing of heat storage unit 14. It is also possible to combine different shapes of heat storage plates 141, 141a in a heat storage unit 14.

German patent application no. 102024102859.9 filed Feb. 1, 2024, to which this application claims priority, is hereby incorporated herein by reference in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A housing for a heat source, comprising:
an outer shell enclosing an interior space;
the heat source configured to intermittently release heat in a first heat flow and arranged in the interior space;
a heat storage unit arranged in the interior space and configured to intermittently store heat released by the heat source in the first heat flow, the heat storage unit comprising at least one heat storage plate;
a heat transport connection fluidly connecting the heat source and the heat storage unit;
a coolant configured to transport heat released by the heat source from the heat source to the heat storage unit via the heat transport connection, the housing configured such that the coolant flows against or around the at least one heat storage plate and the at least one heat storage plate being configured to absorb heat from the coolant;
at least one heat release unit arranged in the outer shell or forming a portion of the outer shell; and
a heat dissipation connection configured to thermally connect the heat storage unit to the at least one heat release unit, wherein the heat dissipation connection is configured to transfer heat intermittently stored in the heat storage unit to the at least one heat release unit with at least a partial a time delay from the heat being released from the heat source in the first heat flow,
wherein the at least one heat release unit is configured to dissipate heat from the housing in a second heat flow, and
wherein the housing is configured such that the first heat flow that can be transferred from the heat source to the heat storage unit via the heat transport connection is greater than the second heat flow that can be dissipated from the housing by the heat release unit.

2. The housing according to claim 1, wherein the heat storage unit comprises a plurality of heat storage plates arranged partially spaced apart from one another in a labyrinth, wherein the coolant flows against or around the plurality of heat storage plates, one after another, and wherein the plurality of heat storage plates are configured to guide the coolant from an interface between the heat transport connection and the heat storage unit, through the heat storage unit, and to an interface between the heat storage unit and the heat dissipation connection.

3. The housing according to claim 1, wherein the at least one heat storage plate is constructed in multiple layers and comprises a material with high thermal conductivity in an outer layer and a material with high heat storage capacity in an inner layer, wherein the outer layer is configured to transfer heat from the coolant to the inner layer and the inner layer is configured to intermittently store heat.

4. The housing according to claim 3, wherein the at least one heat storage plate comprises a phase change material configured to, during the intermittent storage of heat, undergo a phase change from a solid phase to a liquid phase such that the phase change material absorbs latent heat and a phase change from the liquid phase to the solid phase such that the phase change material releases latent heat.

5. The housing according to claim 1, wherein the coolant comprises air, and wherein the housing is configured such that the coolant moves passively by free convection from the heat source, through the heat transport connection, and to the heat storage unit, or
wherein a coolant pump is provided in or on the housing, the coolant pump configured to actively transport the coolant from the heat source, through the heat transport connection, and to the heat storage unit.

6. The housing according to claim 1, where each heat release unit of the at least one heat release unit is configured as an opening in the outer shell of the housing and the heat dissipation connection is configured as a pipe fluidly connecting the heat storage unit to the at least one heat release unit, wherein coolant flowing through the at least one heat release unit to outside the housing is configured to dissipate heat from the housing.

7. The housing according to claim 1, wherein the at least one heat release unit forms a portion of the outer shell and the heat dissipation connection is at least partially formed by coolant located in the interior space, wherein the heat dissipation connection is configured to transport heat from the heat storage unit to the at least one heat release unit by convection and/or heat conduction, wherein the at least one heat release unit comprises at least one heat transfer plate configured to dissipate the second heat flow from the housing by heat conduction.

8. The housing according to claim 1, wherein the at least one heat storage plate comprises a phase change material configured to, during the intermittent storage of heat, undergo a phase change from a solid phase to a liquid phase such that the phase change material absorbs latent heat and a phase change from the liquid phase to the solid phase such that the phase change material releases latent heat.

9. The housing according to claim 1, wherein the first heat flow is at least twice as large as the second heat flow.

10. A charging device for an electrically powered vehicle, comprising:
a housing comprising:
an outer shell enclosing an interior space;
power electronics configured to provide a charging current for the electrically powered vehicle, wherein the power electronics is configured to intermittently release heat in a first heat flow when charging the electrically powered vehicle, and wherein the power electronics are arranged in the interior space;
a heat storage unit arranged in the interior space and configured to intermittently store heat released by the power electronics in the first heat flow, the heat storage unit comprising at least one heat storage plate;
a heat transport connection fluidly connecting the power electronics and the heat storage unit;
a coolant configured to transport heat released by the power electronics from the power electronics to the heat storage unit via the heat transport connection, the housing configured such that the coolant flows against or around the at least one heat storage plate and the at least one heat storage plate being configured to absorb heat from the coolant;
at least one heat release unit arranged in the outer shell or forming a portion of the outer shell; and
a heat dissipation connection configured to thermally connect the heat storage unit to the at least one heat release unit, wherein the heat dissipation connection is configured to transfer heat intermittently stored in the heat storage unit to the at least one heat release unit with at least a partial a time delay from the heat being released from the power electronics in the first heat flow,
wherein the at least one heat release unit is configured to dissipate heat from the housing in a second heat flow, and
wherein the housing is configured such that the first heat flow that can be transferred from the power electronics to the heat storage unit via the heat transport connection is greater than the second heat flow that can be dissipated from the housing by the heat release unit, and
at least one plug-in connector connected to the housing via electrical lines and configured to connect to the electrically powered vehicle.

11. A method for dissipating heat from a heat source, the heat source configured to intermittently release heat in a first heat flow, wherein a housing including the heat source therein comprises:
an outer shell enclosing an interior space including the heat source therein;
a heat storage unit arranged in the interior space and configured to intermittently store heat released by the heat source in the first heat flow, the heat storage unit comprising at least one heat storage plate;
a heat transport connection fluidly connecting the heat source and the heat storage unit;
a coolant configured to transport heat released by the heat source from the heat source to the heat storage unit via the heat transport connection, the housing configured such that the coolant flows against or around the at least one heat storage plate and the at least one heat storage plate being configured to absorb heat from the coolant;
at least one heat release unit arranged in the outer shell or forming a portion of the outer shell; and
a heat dissipation connection configured to thermally connect the heat storage unit to the at least one heat release unit, wherein the heat dissipation connection is configured to transfer heat intermittently stored in the heat storage unit to the at least one heat release unit with at least a partial a time delay from the heat being released from the heat source in the first heat flow,
wherein the at least one heat release unit is configured to dissipate heat from the housing in a second heat flow, and
wherein the housing is configured such that the first heat flow that can be transferred from the heat source to the heat storage unit via the heat transport connection is greater than the second heat flow that can be dissipated from the housing by the heat release unit,
the method comprising:
transferring the first heat flow from the heat source to the heat storage unit via the heat transport connection;
intermittently storing heat from the first heat flow in the heat storage unit; and
dissipating the second heat flow to outside the housing, wherein said dissipating of the second heat flow to outside the housing is carried out with at least a partial time delay to the transferring of the first heat flow, and wherein the first heat flow is greater than the second heat flow, or
intermittently switching off the heat release unit, the heat dissipation connection, and/or the coolant pump such that the intermittently stored heat of the heat storage plates remains in the housing.

12. The method according to claim 11, wherein the heat source is formed by power electronics of a charging device for an electrically powered vehicle, and wherein the transfer of the first heat flow is used to cool the power electronics.
